(19) United States
(12) Patent Application Publication
(10) Pub. No.: US 2024/0213007 A1
(43) Pub. Date: Jun. 27, 2024

(54) Power Compensation in PVD Chambers

(71) Applicant: Applied Materials, Inc., Santa Clara, CA (US)

(72) Inventors: Junjie PAN, Fremont, CA (US); Yida LIN, Santa Clara, CA (US); Xiangjin XIE, Fremont, CA (US); Martin Lee RIKER, Round Rock, TX (US); Suhas UMESH, Sunnyvale, CA (US); Keith A. MILLER, Mountain View, CA (US)

(21) Appl. No.: 18/089,216

(22) Filed: Dec. 27, 2022

(51) Int. Cl. H01J 37/34; C23C 14/35; C23C 14/54

(52) U.S. Cl. CPC H01J 37/3464; C23C 14/35; C23C 14/54; H01J 37/3405; H01J 37/3476; H01J 2237/332

(57) ABSTRACT

Methods and apparatus for controlling processing of a substrate within a process chamber, comprising: performing statistical analysis on measurements of deposition profile of at least one previously processed substrate processed in the process chamber, wherein the deposition profile is based at least on modulating a power parameter of at least one power supply affecting a magnetron in the process chamber; determining, based on the statistical analysis, a model of the deposition profile as a function of at least the power parameter; fitting the measurements of deposition profile to the model; determining a power parameter setpoint for the at least one power supply using the fitted model based on a desired deposition profile of an unprocessed substrate; and setting the power parameter setpoint for processing the unprocessed substrate.

### FIELD

Embodiments of the present disclosure generally relate to plasma processing in semiconductor process chambers.

### BACKGROUND

Sputtering, also known in one application as physical vapor deposition (PVD), is a method of forming metallic features in integrated circuits. In such applications, sputtering deposits a material layer on a substrate. A source material, such as a target, is bombarded by ions strongly accelerated by an electric field. The bombardment ejects material from the target, and the material then deposits on the substrate. In other applications however, sputtering may also be used to etch a substrate. The inventors have observed that, during deposition and etching, ejected particles may travel in varying directions, rather than generally orthogonal to the substrate surface, undesirably resulting in non-uniform deposition and etching of the substrate. In addition, other factors, such as process conditions or process chamber design, can also undesirably affect processing uniformity on the substrate. Also, some factors may have interrelationships with other factors. Due to the number of factors and their possible interrelationships that might influence the uniformity of deposition and etching, a large number of experiments may be used to identify factors causing non-uniformities.

Thus, the inventors propose novel methods, apparatus, and systems to identify factors causing non-uniformities that do not involve such large numbers of experiments and which can be used to correct for such non-uniformities.

### SUMMARY

Methods and apparatus for controlling processing of a substrate within a process chamber are provided herein. In some embodiments, a method of controlling processing of a substrate within a process chamber, includes: performing statistical analysis on measurements of deposition profile of at least one previously processed substrate processed in the process chamber, wherein the deposition profile is based at least on modulating a power parameter of at least one power supply affecting a magnetron in the process chamber; determining, based on the statistical analysis, a model of the deposition profile as a function of at least the power parameter; fitting the measurements of deposition profile to the model; determining a power parameter setpoint for the at least one power supply using the fitted model based on a desired deposition profile of an unprocessed substrate; and setting the power parameter setpoint for processing the unprocessed substrate.

In some embodiments, an apparatus for controlling processing of a substrate within a process chamber including a moveable magnetron and at least one power supply, comprising: a processor; and a memory coupled to the processor, the memory having stored therein instructions executable by the processor to configure the apparatus to: perform statistical analysis on measurements of deposition profile of at least one previously processed substrate processed in the process chamber, wherein the deposition profile is based at least on modulating a power parameter of the at least one power supply affecting the magnetron in the process chamber; determine, based on the statistical analysis, a model of the deposition profile as a function of at least the power parameter; fit the measurements of deposition profile to the model; determine a power parameter setpoint for the at least one power supply using the fitted model based on a desired deposition profile of an unprocessed substrate; and set the power parameter setpoint for processing the unprocessed substrate.

In some embodiments, a substrate processing system includes: a process chamber, comprising: a movable magnetron; and at least one power supply affecting the magnetron; and a controller comprising a processor and a memory coupled to the processor, the memory having stored therein instructions executable by the processor to configure the controller to: perform statistical analysis on measurements of deposition profile of at least one previously processed substrate processed in the process chamber, wherein the deposition profile is based at least on modulating a power parameter of the at least one power supply affecting the magnetron in the process chamber; determine, based on the statistical analysis, a model of the deposition profile as a function of at least the power parameter; fit the measurements of deposition profile to the model; determine a power parameter setpoint for the at least one power supply using the fitted model based on a desired deposition profile of an unprocessed substrate; and set the power parameter setpoint for processing the unprocessed substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic cross-sectional view of a physical vapor deposition (PVD) chamber in accordance with some embodiments of the present disclosure.

FIG. 1B depicts a system in accordance with some embodiments of the present disclosure.

FIG. 2 depicts a high-level block diagram of a system for controlling process uniformity on a substrate within a process chamber in accordance with an embodiment of the present principles.

FIG. 3 depicts a high-level block diagram of a controller suitable for use in the system of FIG. 2 in accordance with an embodiment of the present principles.

FIG. 4 is a flow chart of a method in accordance with embodiments of the present disclosure.

FIG. 5A shows a graphical representation of a deposition profile of a substrate.

FIG. 5B shows a mesh with discrete locations corresponding to locations on the substrate of FIG. 5A.

FIG. 6 shows a graph of thickness vs. angular position for seven substrates processed using different DC power.

FIG. 7 shows a graph of thickness vs. radial position for seven substrates processed using different DC power.

FIG. 8 shows a graph of power compensation vs. thickness for seven substrates at three different radiuses.

To facilitate understanding, identical reference numerals have been used, where possible, to designate identical elements that are common to the Figures. The Figures are not drawn to scale and may be simplified for clarity. Elements and features of one embodiment may be beneficially incorporated in other embodiments without further recitation.

### DETAILED DESCRIPTION

Embodiments of the present principles relate to a high-resolution control system that enables process control based on an angular and/or a radial position of a magnetron in real time. For example, the magnetron position and/or angle may be used as input parameters in control of the power supplies directly affecting the process, thus adding a new layer of control to the resulting deposited films or etched target. Embodiments of the present principles may advantageously reduce, control, or eliminate process rate non-uniformities, such as center-fast, center-slow, and left-right or asymmetrical skew on a substrate, that are induced in plasma process chambers. Skew generally refers to the difference in process results from one region of the substrate to another. By way of illustrative example, the process results may be the amount of material deposited upon a target surface of the substrate, as by a physical vapor deposition operation, or the amount of material removed from the substrate during an etching operation. The skew may be characterized by left vs. right differences, center vs. edge differences, top vs. bottom of a feature, or any combination of these. In some cases, the skew is related to, or otherwise caused by, the previous process chamber used to process the substrate in the process sequence. Additional contributors to skew include asymmetries in flow, pressure, temperature, and power delivery by the RF power applicator used to generate the plasma. Although embodiments of the present principles will be described primarily with respect to a PVD process, the disclosed embodiments should not be considered limiting. Embodiments of the present disclosure may be applied to deposition processes and etching processes.

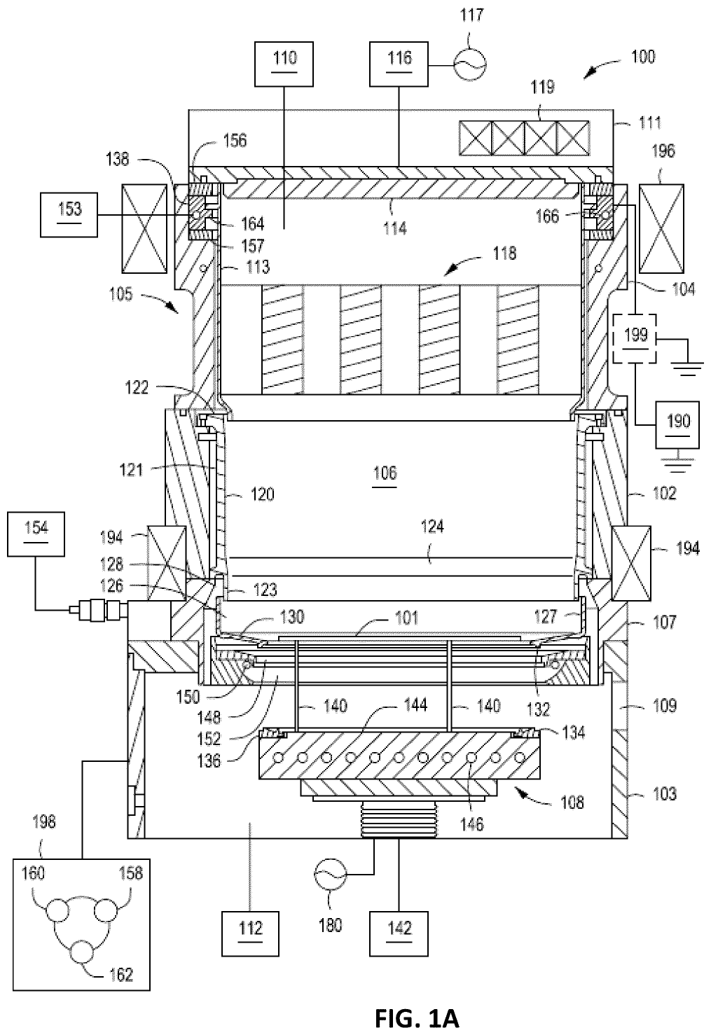

FIG. 1A depicts an illustrative process chamber 100, e.g., a sputter process PVD deposition chamber, suitable for sputter depositing materials on a substrate in accordance with embodiments of the present disclosure. Illustrative examples of suitable PVD chambers that may be adapted to benefit from the disclosure include the ALPS® Plus and SIP ENCORE® and Access® PVD process chambers, both commercially available from Applied Materials, Inc., Santa Clara, of California. Other processing chambers available from Applied Materials, Inc. as well as other manufacturers may also be adapted in accordance with the embodiments described herein.

The process chamber 100 has an upper sidewall 102, a lower sidewall 103, a ground adapter 104, and a lid assembly 111 defining a body 105 that encloses an interior volume 106 thereof. An adapter plate 107 may be disposed between the upper sidewall 102 and the lower sidewall 103. A substrate support, such as a pedestal 108, is disposed in the interior volume 106 of the process chamber 100. A substrate transfer port 109 is formed in the lower sidewall 103 for transferring substrates into and out of the interior volume 106.

In some embodiments, the process chamber 100 is configured to deposit, for example, titanium, aluminum oxide, aluminum, aluminum oxynitride, copper, tantalum, tantalum nitride, tantalum oxynitride, titanium oxynitride, tungsten, tungsten nitride, or other materials, on a substrate, such as the substrate 101.

A gas source 110 is coupled to the process chamber 100 to supply process gases into the interior volume 106. In some embodiments, process gases may include inert gases, non-reactive gases, and reactive gases, if necessary. Examples of process gases that may be provided by the gas source 110 include, but not limited to, argon gas (Ar), helium (He), neon gas (Ne), nitrogen gas (N₂), oxygen gas (O₂), and water (H₂O) vapor, among others.

A pump 112 is coupled to the process chamber 100 in communication with the interior volume 106 to control the pressure of the interior volume 106 to any suitable pressure for a given process. In some embodiments, during deposition the pressure level of the process chamber 100 may be maintained at about 1 Torr or less. In some embodiments, the pressure level of the process chamber 100 may be maintained at about 500 mTorr or less during deposition. In some embodiments, the pressure level of the process chamber 100 may be maintained at about 1 mTorr and about 300 mTorr during deposition.

The ground adapter 104 may support a sputtering source 114, such as a target fabricated from a material to be sputter deposited on a substrate. In some embodiments, the sputtering source 114 may be fabricated from titanium (Ti), tantalum (Ta), tungsten (W), molybdenum (Mo), cobalt (Co), nickel (Ni), copper (Cu), aluminum (Al), alloys thereof, combinations thereof, or the like.

The sputtering source 114 may be coupled to a source assembly 116 comprising a power supply 117 for the sputtering source 114. In some embodiments, the power supply 117 may be an RF power supply. In some embodiments, the power supply 117 may alternatively be a DC power supply. In some embodiments, the power supply 117 may include both DC and RF power sources.

A magnetron assembly (magnetron 119) which includes set of rotatable magnets may be coupled adjacent to the sputtering source 114 which enhances efficient sputtering materials from the sputtering source 114 during processing. Examples of the magnetron 119 include an electromagnetic linear magnetron, a serpentine magnetron, a spiral magnetron, a double-digitated magnetron, a rectangularized spiral magnetron, among others. The magnetron 119 includes at least one motor for controlling the rotation of the magnets. In some embodiments, two motors are provided for controlling the rotation of the magnets. Rotary encoders, position sensors, or the like may be used to provide a signal representative of the angular position of the magnetron 119. The radial position of the magnetron 119 may be calculated from the angular position or may be determined using one or more encoders, position sensors, or the like.

In some embodiments, first magnets 194 may be disposed between the adapter plate 107 and the upper sidewall 102 to assist generating a magnetic field to guide the metallic ions dislodged from the sputtering source 114. Second magnets 196 may be disposed adjacent to the ground adapter 104 to assist generating the magnetic field to guide dislodged materials from the sputtering source 114. The numbers of the magnets disposed around the process chamber 100 may be selected to control plasma dissociation and sputtering efficiency. The first magnets 194 and the second magnets 196 may be electromagnets coupled to a power source for controlling the magnitude of the magnetic field generated by the electromagnets.

An RF power source 180 may be coupled to the process chamber 100 through the pedestal 108 to provide a bias power between the sputtering source 114 and the pedestal 108. In some embodiments, the RF power source 180 may have a frequency between about 400 Hz and about 60 MHz, such as about 13.56 MHz.

The process chamber 100 further includes an upper shield 113 and a lower shield 120. A collimator 118 is positioned in the interior volume 106 between the sputtering source 114 and the pedestal 108. The collimator 118 includes a plurality of apertures to direct gas and/or material flux within the interior volume 106. The collimator 118 is coupled to the upper shield 113 using any fixation means. In some embodiments, the collimator 118 may be formed integrally with the upper shield 113. The collimator 118 may be electrically biased to control ion flux to the substrate and neutral angular distribution at the substrate, as well as to increase the deposition rate due to the added DC bias. Electrically biasing the collimator results in reduced ion loss to the collimator to advantageously enable greater ion/neutral ratios at the substrate. Optionally, a switch 199 may be disposed between the upper shield 113 and the collimator power source 190 to selectively couple the upper shield 113 and collimator 118 to the collimator power source 190.

In some embodiments, the collimator 118 may be electrically biased in bipolar mode so as to control the direction of the ions passing through the collimator 118. For example, a controllable direct current (DC) or AC collimator power source 190 may be coupled to the collimator 118 to provide an alternating pulsed positive or negative voltage to the collimator 118 so as to bias the collimator 118. In some embodiments, the collimator power source 190 is a DC power source.

To facilitate applying bias to the collimator 118, the collimator 118 is electrically isolated from grounded chamber components such as the ground adapter 104. For example, in the embodiment depicted in FIG. 1A, the collimator 118 is coupled to the upper shield 113, which in turn is coupled to the process tool adapter 138. The process tool adapter 138 may be made from suitable conductive materials compatible with processing conditions in the process chamber 100. An insulator ring 156 and an insulator ring 157 are disposed on either side of the process tool adapter 138 to electrically isolate the process tool adapter 138 from the ground adapter 104. The insulator rings 156, 157 may be made from suitable process compatible dielectric materials.

The process tool adapter 138 includes one or more features to facilitate supporting a process tool within the interior volume 106, such as the collimator 118. For example, as shown in FIG. 1A, the process tool adapter 138 includes a mounting ring, or shelf 164 that extends in a radially inward direction to support the upper shield 113. In some embodiments, the mounting ring or shelf 164 is a continuous ring about the inner diameter of the process tool adapter 138 to facilitate more uniform thermal contact with the upper shield 113 mounted to the process tool adapter 138.

In some embodiments, a coolant channel 166 may be provided in the process tool adapter 138 to facilitate flowing a coolant through the process tool adapter 138 to remove heat generated during processing. For example, the coolant channel 166 may be coupled to a coolant source 153 to provide a suitable coolant, such as water. The coolant channel 166 advantageously removes heat from the process tool (e.g., collimator 118) that is not readily transferred to other cooled chamber components, such as the ground adapter 104. For example, the insulator rings 156, 157 disposed between the process tool adapter 138 and the ground adapter 104 are typically made from materials with poor thermal conductivity. Thus, the insulator rings 156, 157 reduce the rate of heat transfer from the collimator 118 to the ground adapter 104 and the process tool adapter 138 advantageously maintains or increases the rate of cooling of the collimator 118. In addition to the coolant channel 166 provided in the process tool adapter 138, the ground adapter 104 may also include a coolant channel to further facilitate removing heat generated during processing.

A radially inwardly extending ledge (e.g., the mounting ring, or shelf 164) is provided to support the upper shield 113 within the central opening within the interior volume 106 of the process chamber 100. In some embodiments the shelf 164 is disposed in a location proximate the coolant channel 166 to facilitate maximizing the heat transfer from the collimator 118 to the coolant flowing in the coolant channel 166 during use.

In some embodiments, the lower shield 120 may be provided in proximity to the collimator 118 and interior of the ground adapter 104 or the upper sidewall 102. The lower shield 120 may include a tubular body 121 having a radially outwardly extending flange 122 disposed in an upper surface of the tubular body 121. The flange 122 provides a mating interface with an upper surface of the upper sidewall 102. In some embodiments, the tubular body 121 of the lower shield 120 may include a shoulder region 123 having an inner diameter that is less than the inner diameter of the remainder of the tubular body 121. In some embodiments, the inner surface of the tubular body 121 transitions radially inward along a tapered surface 124 to an inner surface of the shoulder region 123.

A shield ring 126 may be disposed in the process chamber 100 adjacent to the lower shield 120 and intermediate of the lower shield 120 and the adapter plate 107. The shield ring 126 may be at least partially disposed in a recess 128 formed by an opposing side of the shoulder region 123 of the lower shield 120 and an interior sidewall of the adapter plate 107.

In some embodiments, the shield ring 126 may include an axially projecting annular sidewall 127 that has an inner diameter that is greater than an outer diameter of the shoulder region 123 of the lower shield 120. A radial flange 130 extends from the annular sidewall 127. The radial flange 130 includes a protrusion 132 formed on a lower surface of the radial flange 130. The protrusion 132 may be a circular ridge extending from the surface of the radial flange 130 in an orientation that is substantially parallel to the inside diameter surface of the annular sidewall 127 of the shield ring 126. The protrusion 132 is generally adapted to mate with a recess 134 formed in an edge ring 136 disposed on the pedestal 108. The recess 134 may be a circular groove formed in the edge ring 136. The engagement of the protrusion 132 and the recess 134 centers the shield ring 126 with respect to the longitudinal axis of the pedestal 108.

The substrate 101 (shown supported on lift pins 140) is centered relative to the longitudinal axis of the pedestal 108 by coordinated positioning calibration between the pedestal 108 and a robot blade (not shown). Thus, the substrate 101 may be centered within the process chamber 100 and the shield ring 126 may be centered radially about the substrate 101 during processing.

In operation, a robot blade (not shown) having the substrate 101 disposed thereon is extended through the substrate transfer port 109. The pedestal 108 may be lowered to allow the substrate 101 to be transferred to the lift pins 140 extending from the pedestal 108. Lifting and lowering of the pedestal 108 and/or the lift pins 140 may be controlled by a drive 142 coupled to the pedestal 108. The substrate 101 may be lowered onto a substrate receiving surface 144 of the pedestal 108. With the substrate 101 positioned on the substrate receiving surface 144 of the pedestal 108, sputter deposition may be performed on the substrate 101. The edge ring 136 may be electrically insulated from the substrate 101 during processing. Therefore, the substrate receiving surface 144 may have a height that is greater than a height of portions of the edge ring 136 adjacent the substrate 101 such that the substrate 101 is prevented from contacting the edge ring 136. During sputter deposition, the temperature of the substrate 101 may be controlled by utilizing thermal control channels 146 disposed in the pedestal 108.

In some processes, after sputter deposition, the substrate 101 may be elevated utilizing the lift pins 140 to a position that is spaced away from the pedestal 108. The elevated location may be proximate one or both of the shield ring 126 and a reflector ring 148 adjacent to the adapter plate 107. The adapter plate 107 includes one or more lamps 150 coupled to the adapter plate 107 at a position intermediate of a lower surface of the reflector ring 148 and a concave surface 152 of the adapter plate 107. The lamps 150 provide optical and/or radiant energy in the visible or near visible wavelengths, such as in the infra-red (IR) and/or ultraviolet (UV) spectrum. The energy from the lamps 150 is focused radially inward toward the backside (i.e., lower surface) of the substrate 101 to heat the substrate 101 and the material deposited thereon. Reflective surfaces on the chamber components surrounding the substrate 101 serve to focus the energy toward the backside of the substrate 101 and away from other chamber components where the energy would be lost and/or not utilized. The adapter plate 107 may be coupled to the coolant source 153 or 154 to control the temperature of the adapter plate 107 during heating.

After controlling the substrate 101 to a predetermined temperature, the substrate 101 is lowered to a position on the substrate receiving surface 144 of the pedestal 108. The substrate 101 may be rapidly cooled utilizing the thermal control channels 146 in the pedestal 108 via conduction. The temperature of the substrate 101 may be ramped down from the first temperature to a second temperature in a matter of seconds to about a minute. The substrate 101 may be removed from the process chamber 100 through the substrate transfer port 109 for further processing. The substrate 101 may be maintained at a predetermined temperature range, such as less than 250 degrees Celsius.

A controller 198 is coupled to the process chamber 100. The controller 198 includes a central processing unit (CPU) 160, a memory 158, and support circuits 162. The controller 198 is utilized to control the process sequence, regulating the gas flows from the gas source 110 into the process chamber 100 and controlling ion bombardment of the sputtering source 114. The CPU 160 may be of any form of a general-purpose computer processor that can be used in an industrial setting. The software routines can be stored in the memory 158, such as random-access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 198 that controls the process chamber 100 such that the processes, including the processes disclosed below, are performed in accordance with embodiments of the present disclosure. The software routines may also be stored and/or executed by a second controller (not shown) that is located remotely from the process chamber 100.

In some embodiments, the process chamber 100 is wired for “1 ms or less network latency for digital communications to facilitate control of the process in substantially real time. As used herein, “real time” means within about 1 ms or less.

During processing, material is sputtered from the sputtering source 114 and deposited on the surface of the substrate 101. The sputtering source 114 and the pedestal 108 are biased relative to each other by the power supply 117 or the RF power source 180 to maintain a plasma formed from the process gases supplied by the gas source 110. The DC power applied to the collimator 118 also assists with constant or pulsed power, controlling ratio of the ions and neutrals passing through the collimator 118, advantageously enhancing the trench sidewall and bottom fill-up capability. The ions from the plasma are accelerated toward and strike the sputtering source 114, causing target material to be dislodged from the sputtering source 114. The dislodged target material, and in some embodiments one or more elements from the process gases, forms a layer on the substrate 101.

In operation and with reference to FIG. 1A, the magnetron 119 is positioned behind the sputtering source 114 to enhance the dislodging of target material in an area of the sputtering source 114 proximate the magnetron 119. The inventors determined that the positional information of the magnetron 119 may be used to control a deposition or etching process to, for example, correct for uniformity errors in accordance with the principles described herein.

The process chamber 100 of FIG. 1A is an illustrative example of a process chamber and is not limiting of the scope of the disclosure. In some embodiments in accordance with the present principles, a process chamber can include only some of the components of the process chamber 100 of FIG. 1A. For example, in the process chamber 100 of FIG. 1A, the lamps 150, the reflector rings 148 and the collimator 118 can be considered optional components for some processes performed in the process chamber 100 of FIG. 1A to which embodiments in accordance with the present principles may be applied. In addition, although the process chamber 100 of FIG. 1A is depicted as a PVD chamber to be used for a material deposition process, in some embodiments, the inventive processes described herein can be applied to a sputter etching process in which the substrate to be etched may be considered the ‘target’.

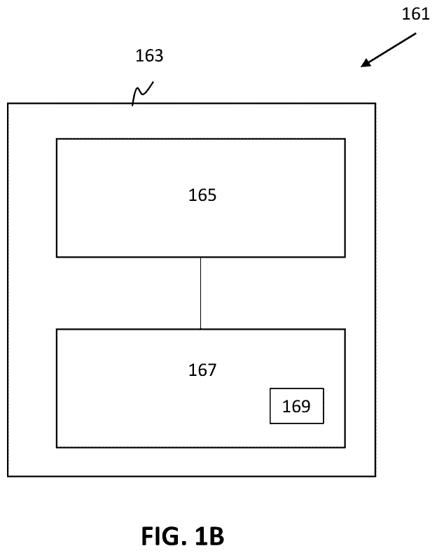

FIG. 2 depicts a high-level block diagram of a system 200 for controlling process uniformity on a substrate within, for example a physical vapor deposition (PVD) chamber or an etching chamber, in accordance with an embodiment of the present principles. The system 200 of FIG. 2 illustratively comprises a controller 202 and a process chamber, such as the process chamber 100 of FIG. 1A or, alternatively, another process chamber such as process chamber 165 shown in FIG. 1B, which may be an etching chamber. In various embodiments in accordance with the present principles, the controller 202 of FIG. 2 can comprise the controller 198 of FIG. 1A or, in alternate embodiments, the controller 202 can be a second controller as described above with reference to controller 198 of FIG. 1A. FIG. 2 further illustratively depicts a representation of the power supplies 204 1-204 n, collectively power supplies 204, associated with the various components of the process chamber 100. Such power supplies can include DC or RF source power supply (e.g., power supply 117), RF bias power supply (e.g., RF power source 180), AC or DC shield bias voltage supply (e.g., collimator power source 190), electromagnetic coil current supply (e.g., current supplied to first magnets 194 and/or second magnets 196), or any other power supplies affecting substrate processing.

The system 200 of FIG. 2 may include motors 208, 209 for controlling the rotation of the magnets of the magnetron 119. The system 200 of FIG. 2 further illustratively includes a two-axis driver 206 for controlling the rotation of the respective motors 208, 209 used to position the magnetron 119 of the process chamber 100. In FIG. 2, the power supplies 204, the two-axis driver 206 and the respective motors 208, 209 are depicted as components separate from the process chamber 100, however, in alternate embodiments in accordance with the present principles, the power supplies 204, the two-axis driver 206 and the respective motors 208, 209 may comprise integrated components of the process chamber 100.

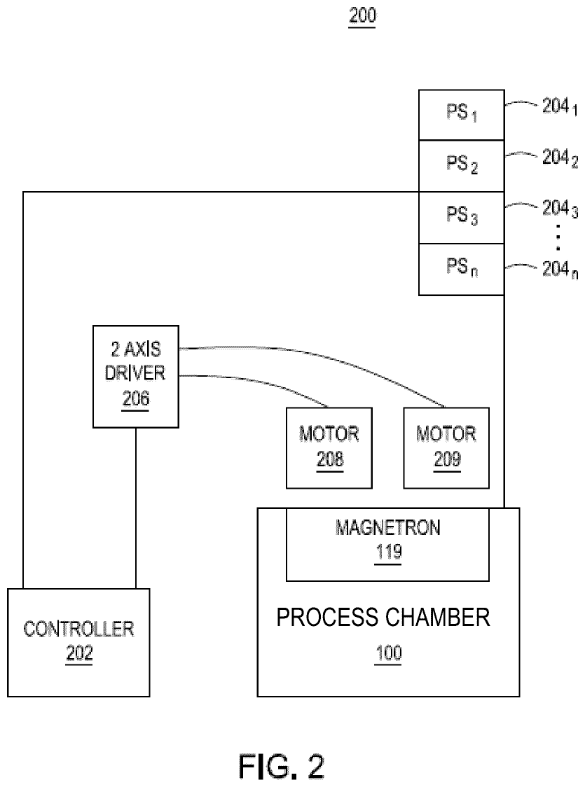

FIG. 3 depicts a high-level block diagram of a controller 202 suitable for use in the system 200 of FIG. 2 in accordance with an embodiment of the present principles. The controller 202 of FIG. 3 comprises a processor 310 as well as a memory 320 for storing power control function types, such as functional curves, control programs, buffer pools and the like. The processor 310 cooperates with support circuitry 330 such as power supplies, clock circuits, cache memory and the like as well as circuits that assist in executing the software routines/programs stored in the memory 320. As such, some of the process steps discussed herein as software processes may be implemented within hardware, for example, as circuitry that cooperates with the processor 310 to perform various steps. The controller 202 also contains input-output circuitry 340 that forms an interface between the various functional elements communicating with the controller 202. As depicted in the embodiment of FIG. 3, the controller 202 can further include a display 350. The display 350 of the controller 202 may be used to present to a user, functional curves to be applied to power supplies affecting the deposition process, results of a deposition process having a functional curve applied in accordance with the teachings herein and the like.

Although the controller 202 of FIG. 3 is depicted as a general purpose computer, the controller 202 is programmed to perform various specialized control functions in accordance with the present principles and embodiments of the controller 202 can be implemented in hardware, for example, as an application specified integrated circuit (ASIC). As such, the process steps described herein are intended to be broadly interpreted as being equivalently performed by software, hardware, or a combination thereof.

In various embodiments in accordance with the present principles, a substrate is processed in a suitable process chamber (such as the process chamber 100 of FIG. 1A) to deposit material on the substrate. In such embodiments, the deposition rate on a surface of the substrate is measured to determine a deposition profile for the deposition process on the surface of the substrate. If any areas of undesired deposition (e.g., non-uniform) deposition are detected, a location of the undesired (e.g., non-uniform) deposition on the surface of the substrate and a rate (amount) of the undesired (e.g., non-uniform) depositions are determined. In some embodiments, a substrate is processed in a suitable process chamber (such as the process chamber 100 of FIG. 1A) to etch or remove material from the substrate. In such embodiments, an etching rate on a surface of the substrate is measured to determine an etching profile for the etching process on the surface of the substrate. Similarly, if any areas of undesired (e.g., non-uniform) etching are detected, a location of the undesired (e.g., non-uniform) etching on the surface of the substrate and a rate (amount) of the undesired (e.g., non-uniform) etching are determined. The profile information and measurements are communicated to the controller 202.

In some embodiments, and as shown in FIG. 1B a system 161 may include a cluster tool 163 having a process chamber 165 and a metrology chamber 167. The process chamber 165 may be the process chamber 100 of FIG. 1, or may be another process chamber, such as an etching chamber. In some embodiments, the deposition rate on a surface of substrate being processed may be measured by a measurement system 169 that may include one or more devices configured for at least one of resistance measurement, x-ray florescence (XRF), or ellipsometry. In some embodiments, and as shown in FIG. 1B, the measurement system 169 may be located in the metrology chamber 167. In alternate embodiments, in accordance with the present principles directed to an etching process, a substrate may be measured using the measurement system 169, for example using XRF, before and after an etch process to detect how much material is removed from the substrate surface. Thus, the measurement system 169 may be used for obtaining the measurements of the deposition profile after one (i.e., each) or more unprocessed substrate is processed in the process chamber. Although specific examples are provided herein for measuring a deposition rate and an etch rate, the examples should not be considered as limiting. In alternate embodiments in accordance with the present principles, any known or not yet know methods or means for measuring/determining a deposition rate and an etch rate can be implemented in accordance with the present principles.

By having a cluster tool 163 with both the process chamber 165 and the metrology chamber 167, material handling times between the process chamber 165 and the metrology chamber 167 may be reduced in comparison to an example where the metrology chamber 167 is separated from the process chamber 165. As a result, measurements of deposition profiles of substrates may be fed back more quickly to the controller 202 so that more frequent adjustments can be made to power parameters used in substrate processing in the process chamber 165. Thus, tighter process control and higher process yield may be achieved.

In various embodiments in accordance with the present principles, the controller 202 determines positions of the magnetron 119 relative to reference locations on a surface of a substrate to be processed. In one embodiment in accordance with the present principles, a position of the magnetron 119 relative to a surface of a substrate may be determined by the controller 202 using motor encoder information provided to the controller 202 by the two-axis driver 206. In some embodiments, home flags may establish a zero angular position for the magnetron 119 with respect to a surface of a substrate being processed and may detect that angular position when the magnet passes the home flag sensor (e.g., once per revolution). In alternate embodiments, information regarding positions of the magnetron 119 relative to reference locations on a surface of a substrate may be retrieved from a memory 320 of the controller 202, having been previously determined and stored in the memory 320 of the controller 202.

In accordance with the present principles, a power parameter, such as a power set point (or when referring to multiple locations, a power profile), of a power supply affecting substrate processing is modulated to control a deposition or etching rate at a location on the surface of the substrate based on a position of a magnetron, such as the magnetron 119. With reference to the process chamber 100 of FIG. 1A, in some embodiments such power parameters of power supplies to be modulated can illustratively include power set points of a DC or RF source power (e.g., power supply 117), RF bias power (e.g., RF power source 180), AC or DC shield bias voltage (e.g., collimator power source 190), electromagnetic coil current (e.g., current supplied to first magnets 194 and/or second magnets 196), or any other power supplies affecting the substrate processing. In one embodiment in accordance with the present principles, the power set point of a power supply may refer to an amount of power to be supplied by that power supply at a specific time during the processing of a substrate or an amount of power to be supplied by that power supply at a specific location on the surface of a substrate. As such, in embodiments in accordance with the present principles, an amount of power to be provided by a power supply (e.g., power supply 204) may be modulated (e.g., increased or decreased) as described herein to control a deposition rate or etching rate at a location on the surface of the substrate based on a position of the magnetron (e.g., magnetron 119).

For example, in various embodiments in accordance with the present principles, a deposition rate and/or etching rate is controlled to correct for areas on the surface of the substrate having non-uniform deposition or etching rates. Using information regarding locations on the surface of the substrate which contain non-uniform depositions or etching, which can be determined using previously determined deposition and etching profiles, and information regarding positions of the magnetron 119 relative to reference locations on a surface of a substrate, the controller 202 may communicate a signal to modulate a power profile of one or more power supplies, such as the power supplies 204, based on an angular and/or radial position of the magnetron 119 to correct the areas of the non-uniform processing.

In various embodiments in accordance with the present principles, increasing a power profile of a power supply 204 increases a deposition rate of target material on a substrate at a location on the surface of the substrate relative to the position of the magnetron 119. Conversely, decreasing a power profile of a power supply 204 decreases a deposition rate of target material on a substrate at a location on the surface of the substrate relative to the position of the magnetron 119. In some embodiments, increasing a power profile of a power supply 204 decreases a deposition rate of target material on a substrate at a location on the surface of the substrate relative to the position of the magnetron 119 and decreasing a power profile of a power supply 204 increases a deposition rate of target material on a substrate at a location on the surface of the substrate relative to the position of the magnetron 119.

In accordance with the present principles, a location on a surface of a substrate on which target material is being deposited may be identified using a position of the magnetron 119. As such, in accordance with embodiments of the present principles, a determination may be made when to adjust a power profile of one or more power supplies 204 to adjust a rate of material deposition at a corresponding location on the surface of a substrate being processed, which may be used to correct for non-uniform deposition.

The above-described embodiments are not mutually exclusive. In various embodiments in accordance with the present principles, combinations of the above-described embodiments are also possible. For example, a deposition process with axial non-uniformity combined with off-axis non-uniformity may be adjusted by controlling power inputs based upon both radial and angular positions of the magnetron. In addition to non-uniform deposition processes, in alternate embodiments in accordance with the present principles, the same process can be applied to a non-uniform etching process. In such embodiments directed to a non-uniform etching process, locations on a surface of a substrate having non-uniform etching are measured and identified as described above. The non-uniform etching process may be corrected by controlling the power profiles of one or more power supplies based upon an angular or radial position of the magnetron 119. For example, power supplies that impact substrate processing, such as power supplies 204, may be modulated based upon an angular or radial position of the magnetron 119 to correct for non-uniform etching in locations on the surface of the substrate relative to the angular or radial positions of the magnetron 119. Such modulation may include increasing or decreasing the power profile of one or more of the power supplies 204 to alter the etching rate in the respective areas.

In accordance with various embodiments of the present principles, various function types or shapes (e.g., linear, curved, quadratic, sinusoidal, or the like) may be implemented to adjust a power profile of one or more power supplies based on an angular or radial position of the magnetron. For example, and as described herein, in accordance with embodiments of the present principles, a function type (e.g., a functional curve) may be determined for use in adjusting the set points of one or more power supplies of a deposition process/etching process for adjusting a deposition rate/etching rate on a surface of a substrate being processed based on a position of a magnetron. The function types determined are applicable for respective deposition processes/etching processes having parameters for which the function was determined. If any parameters of the deposition process/etching process are altered (e.g., a change in the process gas, substrate, power supply settings, processing times, etc.), a new function type (e.g., functional curve) may be determined in accordance with the present principles. The various function types may be stored in, for example, the memory 320 of the controller 202 to be recalled by, for example, the controller 202 for application to power supplies of a deposition processes having parameters for which a respective function type was determined. Also, the various function types may be determined using the controller 202.

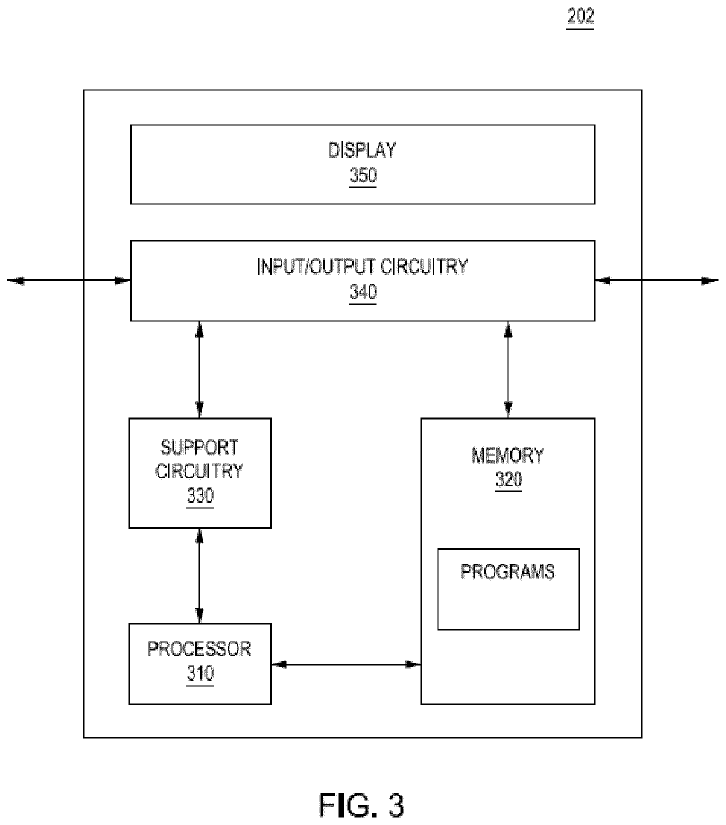

FIG. 4 is a flow chart of a method 400 of controlling processing of a substrate within a process chamber, such as process chamber 100, in accordance with embodiments of the present disclosure. The method 400 may be used to determine a function type to adjust a power profile of one or more power supplies, such as the power supplies 204, based on angular and/or radial position of the magnetron, as discussed above. At 402, the method 400 may begin by obtaining measurements of a deposition profile of at least one previously processed substrate that was processed in a process chamber, such as process chamber 100. In some embodiments, the measurements may consist of measurements of from single previously processed substrate processed immediately before an unprocessed substrate is processed. Thus, in some embodiments, information from processing an immediately preceding substrate may be used as feedback to adjust processing for the next unprocessed substrate.

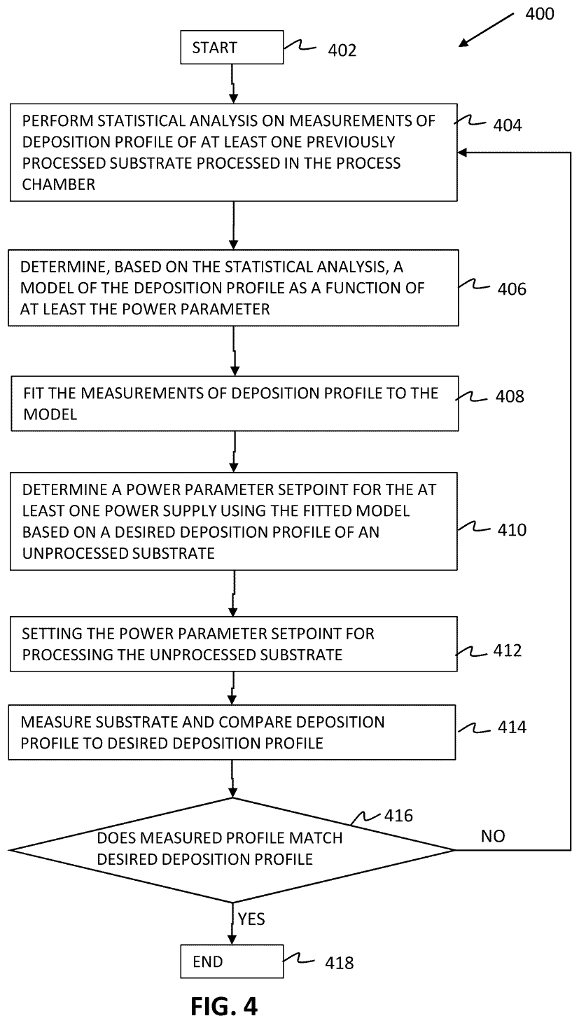

Also, the measurements may include measurements from multiple previously processed substrates. For example, FIG. 5A shows an illustrative graphical representation of a deposition profile on a substrate 500 processed in a process chamber. Six other different substrates may be processed in the same process chamber as substrate 500 to obtain multiple deposition profiles of substrates. For example, for each of the multiple substrates, the DC power applied for all magnetron positions during deposition may be varied. For example, the DC power may be increased or decreased 2.5%, 5%, and 10% in comparison to the DC power used for processing the substrate 500. An edge portion 502, a middle portion 504, and a center portion 506 of substrate 500a are depicted in FIG. 5A as generally annular or circular areas.

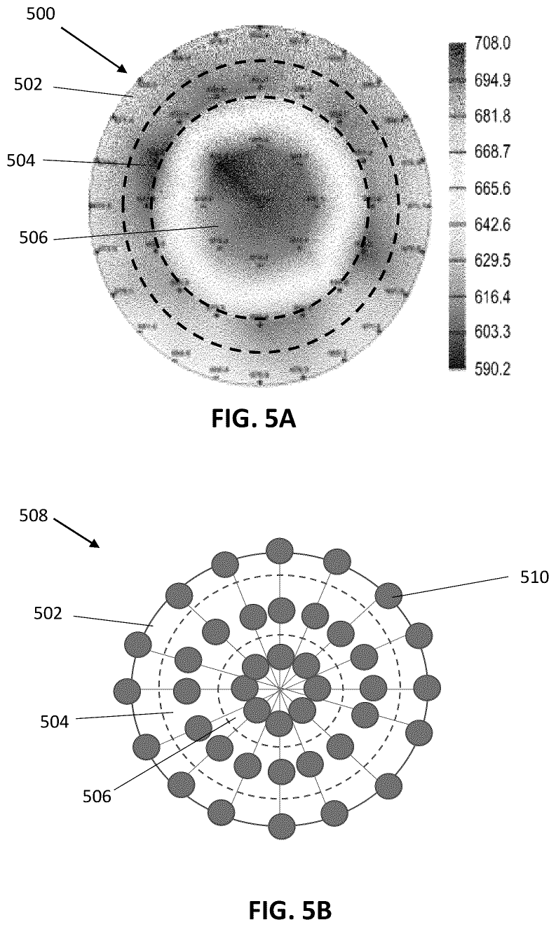

At 404, a statistical analysis may be performed on measurements of deposition profile of at least one previously processed substrate processed in the process chamber. In some embodiments, the statistical analysis may include a regression analysis. Measurements may be obtained or interpolated for discrete locations of the substrate 500 using data from a deposition profile, such as the deposition profile shown in FIG. 5A. For example, FIG. 5B shows an embodiment of a mesh 508 with sixteen discrete measurement locations 510 corresponding to locations in the edge portion 502 of the substrate 500. Also, as shown in FIG. 5B, one or more locations may be in the middle portion 504 and the center portion 506. The mesh 508 shown in FIG. 5B may be made finer by having additional measurement locations 510 in the portions 502, 504, and 506 and/or in additionally defined portions. For example, FIG. 6 illustratively shows the effect of DC power on film thickness (otherwise referred to herein as “thickness”) variation along the edge portion 502 of the substrate 500 and the six other substrates discussed above as a function of angular position of the magnetron. Although specific illustrative examples are provided in FIG. 6, the examples should not be considered as limiting. A regression analysis of the measurements of the deposition profile shown in FIG. 6 may be used to determine that the thickness at each position on the edge portion 502 is a function of a power parameter (e.g., DC power).

At 406, based on the statistical analysis, a model of the deposition profile may be determined as a function of at least the power parameter. For example, in the example based on the deposition profile of substrate 500 and the six other substrates discussed above, the thickness may be represented as a polynomial function:

$$\\ \begin{matrix}f ( {θ}_{n} , P ) = {α}_{0} + {α}_{1} P + {α}_{2} {P}^{{}_{} 2} + … & ( 1 )\end{matrix}$$

where P represents a power parameter (e.g., DC power), and θ represents angular position of the magnetron in the edge portion with respect to a reference position on the substrate. As noted above, in some embodiments, the portion 502 may be divided into twenty-four equally spaced locations. Thus, for example, the equation (1) may be used to represent the relationship between thickness and power for each of such twenty-four locations.

At 408, the measurements of deposition profile may be fit to the model. For example, polynomial fitting of the measurements of the deposition profiles of the substrate 500 and the six other substrates discussed above may be performed to obtain α₀, α₁, α₂, . . . αₙ in equation (1).

At 410, a power parameter setpoint, such as for at least one of the power supplies 204, may be determined using the fitted model based on a desired deposition profile of an unprocessed substrate. For example, a goal for the thickness of the edge portion 502 may be set for all angular positions θ as:

$$\\ \begin{matrix}{f}^{{}_{} *} ( P ) ≡ {\sum }_{1}^{n} f ( {θ}_{n} ) / n , & ( 2 )\end{matrix}$$

which may be set equal to equation (1) as:

$$\\ \begin{matrix}f ( {θ}_{n} , P ) = {α}_{0} + {α}_{1} P + {α}_{2} {P}^{{}_{} 2} + … = {f}^{{}_{} *} ( P ) . & ( 3 )\end{matrix}$$

At 412, the power parameter setpoint may be set for processing an unprocessed substrate. In some embodiments, after the unprocessed substrate is processed using the power parameter setpoint, the substrate may be measured at 414 (such as by the measurement system 169 of metrology chamber 167) to obtain a deposition profile which can be compared to the desired deposition profile at 416. If the measured deposition profile does not match the desired deposition profile (NO at 416), 404-414 may be repeated for processing another unprocessed substrate. For example, if the measured deposition profile deviates more than or equal to a threshold amount, the measured deposition profile may be determined not to match the desired deposition profile. However, if the measured deposition profile matches the desired deposition profile (YES at 416), the method may end at 418. For example, if the measured deposition profile deviates less than a threshold amount, the measured deposition profile may be determined to match the desired deposition profile.

In the example discussed above with reference to substrate 500 and the six other substrates discussed above, the statistical analysis indicated that the thickness at each position on the edge portion 502 is a function of a power parameter P only. In another embodiment, a statistical analysis of the profile measurements may indicate that the thickness at each position, e.g., on the edge portion 502, is a function of both angular position θ and power parameter P, so that a model of the deposition profile may be represented as:

$$\\ \begin{matrix}f ( θ , P ) = {α}_{0} + {α}_{1} θ + {α}_{2} {θ}^{{}_{} 2} + … … + {α}_{n} {θ}^{{}_{} n} , & ( 4 )\end{matrix}$$

where α₀ to αₙ and γ₀ to γₙ may be expressed as:

$$\\ \begin{matrix}{α}_{0} = {γ}_{0}^{{}_{} 0} + {γ}_{1}^{{}_{} 0} P + {γ}_{2}^{{}_{} 0} {P}^{{}_{} 2} + {γ}_{3}^{{}_{} 0} {P}^{{}_{} 3} & ( 5 )\end{matrix}$$

$$\\ \begin{matrix}{α}_{1} = {γ}_{0}^{{}_{} 1} + {γ}_{1}^{{}_{} 1} P + {γ}_{2}^{{}_{} 1} {P}^{{}_{} 2} + {γ}_{3}^{{}_{} 1} {P}^{{}_{} 3} & ( 6 )\end{matrix}$$

$$\\ \begin{matrix}{α}_{n} = {γ}_{0}^{{}_{} n} + {γ}_{1}^{{}_{} n} P + {γ}_{2}^{{}_{} n} {P}^{{}_{} 2} + {γ}_{3}^{{}_{} n} {P}^{{}_{} 3} . & ( 7 )\end{matrix}$$

Polynomial fitting of the measurements of the deposition profiles from of the substrate 500 and the six other substrates discussed above may be performed to obtain α₀ to αₙ and γ₀ to γₙ for the edge portion 502 of the substrate 500 and the six other substrates. A goal for the thickness of the edge portion 502 may be set for all angular positions θ and the goal for the thickness of the edge portion 502 can be set equal to equation (4) to determine power setpoints for each angular position θ for the edge portion 502:

$$\\ \begin{matrix}f \text{?} ( θ , P ) = {α}_{0} + {α}_{1} θ + {α}_{2} {θ}^{{}_{} 2} + … … + {α}_{n} {θ}^{{}_{} n} & ( 8 )\end{matrix}$$

$$\\ \begin{matrix}= ( {γ}_{0}^{{}_{} 0} + {γ}_{1}^{{}_{} 0} P + {γ}_{2}^{{}_{} 0} {P}^{{}_{} 2} + {γ}_{3}^{{}_{} 0} {P}^{{}_{} 3} ) + ( {γ}_{0}^{{}_{} 1} + {γ}_{1}^{{}_{} 1} P + {γ}_{2}^{{}_{} 1} {P}^{{}_{} 2} + {γ}_{3}^{{}_{} 1} {P}^{{}_{} 3} ) θ + … + ( {γ}_{0}^{{}_{} n} + {γ}_{1}^{{}_{} n} P + {γ}_{2}^{{}_{} n} {P}^{{}_{} 2} + {γ}_{3}^{{}_{} n} {P}^{{}_{} 3} ) {θ}^{{}_{} n} & ( 9 )\end{matrix}$$

$$\\ \begin{matrix}= ( {γ}_{0}^{{}_{} 0} + {γ}_{0}^{{}_{} 1} θ + … + {γ}_{0}^{{}_{} n} {θ}^{{}_{} n} ) + ( {γ}_{1}^{{}_{} 0} + {γ}_{1}^{{}_{} 1} θ + … + {γ}_{1}^{{}_{} n} {θ}^{{}_{} n} ) P + ( {γ}_{2}^{{}_{} 0} + {γ}_{2}^{{}_{} 1} θ + … + {γ}_{2}^{{}_{} n} {θ}^{{}_{} n} ) {P}^{{}_{} 2} + ( {γ}_{3}^{{}_{} 0} + {γ}_{3}^{{}_{} 1} θ + … + {γ}_{3}^{{}_{} n} {θ}^{{}_{} n} ) {P}^{{}_{} 3} & ( 10 )\end{matrix}$$

$$\\ \begin{matrix}= [ \begin{matrix}{γ}_{0}^{{}_{} 0} & {γ}_{0}^{{}_{} 1} & ⋯ & {γ}_{0}^{{}_{} n} \\ {γ}_{1}^{{}_{} 0} & {γ}_{1}^{{}_{} 1} & ⋯ & {γ}_{1}^{{}_{} n} \\ {γ}_{2}^{{}_{} 0} & {γ}_{2}^{{}_{} 1} & ⋯ & {γ}_{2}^{{}_{} n} \\ {γ}_{3}^{{}_{} 0} & {γ}_{3}^{{}_{} 1} & ⋯ & {γ}_{3}^{{}_{} n}\end{matrix} ] [ \begin{matrix}1 \\ θ \\ ⋯ \\ {θ}^{{}_{} n}\end{matrix} ] [ \begin{matrix}1 \\ P \\ {P}^{{}_{} 2} \\ {P}^{{}_{} 3}\end{matrix} ] = [ {f}^{{}_{} *} ( θ ) & ( 11 )\end{matrix}$$

$$\\ \text{?} \text{indicates text missing or illegible when filed}$$

Once the power parameter setpoints for the edge portion 502 of the substrate are determined, polynomial fitting of the measurements of the deposition profiles from of the substrate 500 and the six other substrates discussed above may be performed to obtain α₀-αₙ and γ₀-γₙ for the middle portion 504 and the center portion 506 of the substrates. The power parameter setpoints determined for the edge portion 502 can then be input to predict a thickness profile f_{c}(δ,P) for the center portion 506 of the substrate and a thickness profile fₘ(θ,P) for the middle portion 504 of the substrate:

$$\\ \begin{matrix}{f}_{c} ( θ , P ) = {[ \begin{matrix}{γ}_{0}^{{}_{} 0} & {γ}_{0}^{{}_{} 1} & ⋯ & {γ}_{0}^{{}_{} n} \\ {γ}_{1}^{{}_{} 0} & {γ}_{1}^{{}_{} 1} & ⋯ & {γ}_{1}^{{}_{} n} \\ {γ}_{2}^{{}_{} 0} & {γ}_{2}^{{}_{} 1} & ⋯ & {γ}_{2}^{{}_{} n} \\ {γ}_{3}^{{}_{} 0} & {γ}_{3}^{{}_{} 1} & ⋯ & {γ}_{3}^{{}_{} n}\end{matrix} ]}_{c} [ \begin{matrix}1 \\ θ \\ ⋯ \\ {θ}^{{}_{} n}\end{matrix} ] [ \begin{matrix}1 \\ P \\ {P}^{{}_{} 2} \\ {P}^{{}_{} 3}\end{matrix} ] & ( 12 )\end{matrix}$$

$$\\ \begin{matrix}{f}_{m} ( θ , P ) = {[ \begin{matrix}{γ}_{0}^{{}_{} 0} & {γ}_{0}^{{}_{} 1} & ⋯ & {γ}_{0}^{{}_{} n} \\ {γ}_{1}^{{}_{} 0} & {γ}_{1}^{{}_{} 1} & ⋯ & {γ}_{1}^{{}_{} n} \\ {γ}_{2}^{{}_{} 0} & {γ}_{2}^{{}_{} 1} & ⋯ & {γ}_{2}^{{}_{} n} \\ {γ}_{3}^{{}_{} 0} & {γ}_{3}^{{}_{} 1} & ⋯ & {γ}_{3}^{{}_{} n}\end{matrix} ]}_{m} [ \begin{matrix}1 \\ θ \\ ⋯ \\ {θ}^{{}_{} n}\end{matrix} ] [ \begin{matrix}1 \\ P \\ {P}^{{}_{} 2} \\ {P}^{{}_{} 3}\end{matrix} ] & ( 13 )\end{matrix}$$

Also, equation (1) may be used to obtain a functional relationship between power and thickness for the middle portion 504 and the center portion 506. As noted above, data from a deposition profile such as shown in FIG. 5A may be used to generate a mesh 508 like that shown in FIG. 5B. In FIG. 5B, measurement locations 510 of the middle portion 504 are radially aligned with measurement locations of the edge portion 502. Thus, for example, the thickness measurements from the deposition profile at each measurement location 510 of the middle portion 504 can be used in equation (1) to obtain a functional relationship between power and thickness. Once the thickness of a measurement location 510 of the middle portion 504 is modeled using equation (1), the power parameter setpoints obtained using equation (3) for the edge portion 502 can be input into equation (1) to obtain predicted thicknesses for each measurement location 510 of the middle portion 504.

Once the power parameter setpoints and predicted thickness profile are determined, the power parameter setpoints may be used in processing (e.g., deposition or etch processing) an unprocessed substrate. After such processing, the processed substrate may be measured to determine a deposition profile of the substrate. The measured deposition profile can be compared against the predicted thickness profile to evaluate the models used in determining the power parameter setpoints and the predicted thickness profile. In some embodiments, the root mean square error of the difference between measured deposition profile and predicted thickness profile can be obtained to evaluate the validity of the model. If the error exceeds permissible limits, the model(s) may be updated based on the measured deposition profile of the processed substrate to calculate new power parameter setpoints.

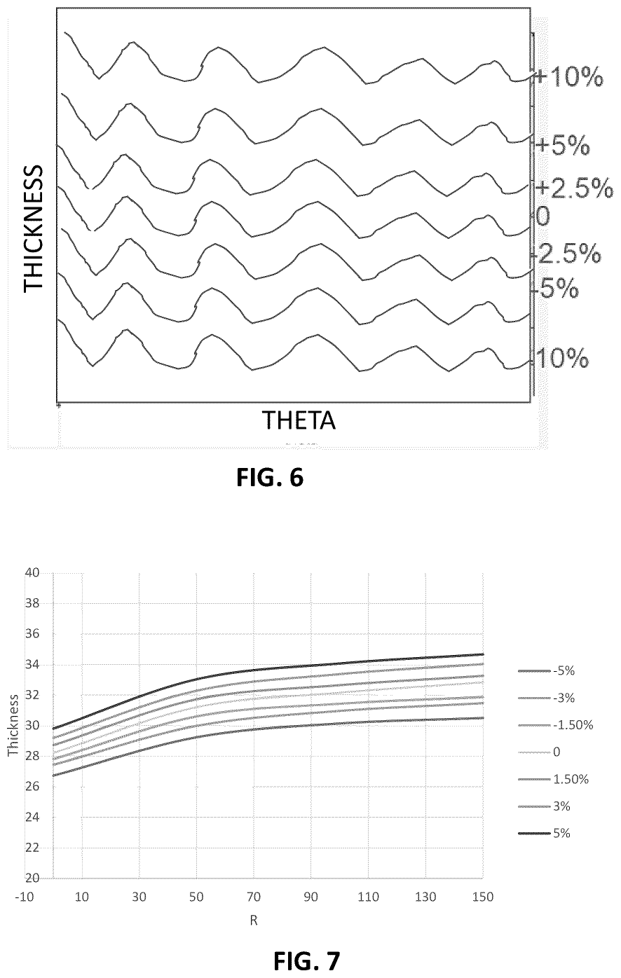

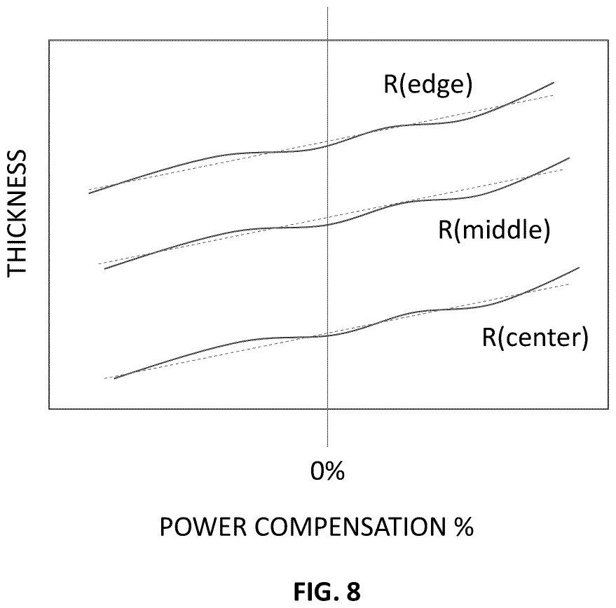

In another embodiment, a statistical analysis of the profile measurements may indicate that the thickness of substrate 500 is a function of both radius r and power parameter P. For example, FIG. 7 shows a graph of thickness versus radius for substrate 500 and six other substrates processed with varying power compensation varying from −5% to +5% and FIG. 8 shows a graph of power compensation versus thickness for the substrate 500 and the six other substrates where thickness measurements are taken at an average radius in each of the edge portion 502, middle portion 504, and center portion 506. As shown in FIG. 8, a linear regression line (shown in dotted line) is fit to the data for each radius r.

In some embodiments, the thickness of the substrate 500 may be represented as shown in equations (4)-(7), but where θ is replaced with r. In using equations (4)-(7) simplifying assumptions may be made. For example, measurements of thicknesses from deposition profiles of each substrate 500 may be averaged for each of the edge portion 502, middle portion 504, and center portion 506. Also, the goals for the thickness of the edge portion 502, middle portion 504, and center portion 506 may be set to a same value, for example, an average thickness for all portions.

Polynomial fitting of the measurements of the deposition profiles from of the substrate 500 and the six other substrates discussed above may be performed to obtain α₀ to αₙ and γ₀ to γₙ for the substrate 500 and the six other substrates. A goal for the average thickness of the edge portion 502 may be set equal to equation (4) (as modified as noted above for radius r) to determine power parameter setpoints for each measurement location 510 at radial position r using the equations (8)-(11), but where θ is replaced with r. The foregoing procedure using equations (4)-(11) may be repeated for each of the middle portion 504 and the center portion 506 to determine power parameter setpoints for the measurement positions 510 at the average radius r of each of those portions.

Alternatively, equation (1) may be used in place of equations (4)-(11) to model the thickness profile of the substrate 500 and six other substrates. For example, for each of the edge portion 502, middle portion 504, and the center portion 506, an average thickness and average radius r may be used in equation (1) to fit α₀-αₙ. In the example of the first order linear regression lines shown in FIG. 8, only α₀ and α₁ may be used. Then, a goal thickness (average thickness) for each of the edge portion 502, middle portion 504, and center portion 506 can be set to determine power parameter setpoints for any measurement locations 510 on the substrate at respective radius r of the edge portion 502, middle portion 504, and center portion 506.

In another embodiment, a statistical analysis of the profile measurements may indicate that the thickness at each position on the edge portion 502 is a function of both radius, angular position, and power parameter P. Thus, in some embodiments, power parameter can be compensated by both r and angular position θ. For example, as discussed above, a power parameter setpoint vector P_{θ} may be obtained from equations (11)-(13) as:

$$\\ \begin{matrix}{P}_{θ} = [ \begin{matrix}{P}_{{θ}_{1}} \\ {P}_{{θ}_{2}} \\ {P}_{{θ}_{3}} \\ ⋯ \\ ⋯ \\ {P}_{{θ}_{m}}\end{matrix} ] & ( 14 )\end{matrix}$$

Also, a power parameter setpoint vector Pᵣ may be obtained similarly from equations (11)-(13), where θ is replaced with r, as described above:

$$\\ \begin{matrix}{P}_{r} = [ \begin{matrix}{P}_{{r}_{1}} \\ {P}_{{r}_{2}} \\ {P}_{{r}_{3}} \\ ⋯ \\ ⋯ \\ {P}_{{r}_{n}}\end{matrix} ] & ( 15 )\end{matrix}$$

In some embodiments, the final power parameter setpoints based on radial position r and angular position θ may be represented as a matrix by coupling the power parameter vectors P_{θ} and Pᵣ as follows:

$$\\ \begin{matrix}{P}_{r θ} = {P}_{θ} {P}_{r}^{{}_{} T} = \begin{matrix}\begin{matrix} & r \text{?} r \text{?} r \text{?} \begin{matrix}\end{matrix}\end{matrix} \\ \begin{matrix}\begin{matrix}\begin{matrix}\begin{matrix}\begin{matrix}{θ}_{1} \\ {θ}_{2}\end{matrix} \\ \end{matrix} \\ \end{matrix} \\ {θ}_{n}\end{matrix} & [ & \begin{matrix}{P}_{{θ}_{1}} {P}_{{r}_{1}} & {P}_{{θ}_{1}} {P}_{{r}_{2}} & ⋯ & {P}_{{θ}_{1}} {P}_{{r}_{n}} \\ {P}_{{θ}_{2}} {P}_{{r}_{1}} & {P}_{{θ}_{2}} {P}_{{r}_{2}} & ⋯ & {P}_{{θ}_{2}} {P}_{{r}_{n}} \\ ⋯ & ⋯ & ⋯ & ⋯ \\ ⋯ & ⋯ & ⋯ & ⋯ \\ {P}_{{θ}_{m}} {P}_{{r}_{1}} & {P}_{{θ}_{m}} {P}_{{r}_{2}} & ⋯ & {P}_{{θ}_{m}} {P}_{{r}_{n}}\end{matrix} & ]\end{matrix}\end{matrix} & ( 16 )\end{matrix}$$

$$\\ \text{?} \text{indicates text missing or illegible when filed}$$

By accounting for radial position r and angular position e in determining the power parameter setpoints, it may be possible to reduce radial and planar nonuniformity in a deposition profile in comparison to considering angular position and radial position separately. Also, the methods described herein allow for manipulation of the overall deposition rate or etch rate as needed, for example, by adjusting the functional value in equations (2) and (11).

In another embodiment, the methods described herein may also be used to control an etching process. To control an etching process, an etching model may be obtained using deposition profile measurements of a first substrate that undergoes a deposition process in a process chamber (such as process chamber 100) and a second substrate that undergoes a blanket film process in the same process chamber. The first substrate may undergo a deposition process using low bias, and the second substrate may undergo the same deposition processing as the first substrate, along with an etching processing using high bias. As described above, statistical analysis of measurements of the deposition profile of the first substrate may be used to determine a model of the deposition profile for the deposition process:

$$\\ \begin{matrix}{f}_{deposition} ( θ , P ) = {α}_{0} + {α}_{1} θ + {α}_{2} {θ}^{{}_{} 2} + … … + {α}_{n} {θ}^{{}_{} n} & ( 17 )\end{matrix}$$

As alternatives to equation (17), the deposition thickness may be modeled using equation (1) or by replacing θ with r, as described above. Also, as described above, statistical analysis of measurements of the deposition profile of the second substrate may be used to determine a model of the blanket process:

$$\\ \begin{matrix}{f}_{blanket} ( θ , P ) = {α}_{0} + {α}_{1} θ + {α}_{2} {θ}^{{}_{} 2} + … … + {α}_{n} {θ}^{{}_{} 2} , & ( 18 )\end{matrix}$$

where all α are function of power P as described in other examples. As alternatives to equation (18), the blanket thickness may be modeled using equation (1) or by replacing θ with r, as described above.

The blanket film process and the deposition process both include the same deposition processing. Thus, an assumption may be made that the etch function is the difference between the deposition function and the blanket function:

$$\\ \begin{matrix}{f}_{etch} = {f}_{deposition} - {f}_{blanket} & ( 19 )\end{matrix}$$

Polynomial fitting may be performed for each function f_{deposition} and f_{blanket} as described above in the other examples. Also, goals may be set for the deposition function f_{deposition} or the blanket function f_{blanket} to determine the power parameter setpoints at each specific angular position on the substrate. For example, if goals are set for the deposition function f_{deposition} for thickness at each angular position, the power parameter setpoints can be determined as discussed in other examples, and those power parameter setpoints may be used to predict the deposition profile for substrates undergoing blanket film processing. Also, in view of the relationship in equation (19) a predicted substrate thickness profile, including etch thickness, may be obtained based on blanket film thickness and deposition thickness.

The predicted substrate thickness profile can be used to validate the models used for the prediction. For example, an unprocessed substrate may be processed using power parameter setpoints determined using the models, as described herein. After processing the substrate, a deposition profile of the substrate may be measured and compared to the predicted substrate thickness profile to evaluate the model used in determining the power parameter setpoints and the predicted substrate thickness profile. In some embodiments, the root mean square error of the difference between measured deposition profile and predicted substrate thickness profile can be obtained to evaluate the validity of the model.

In view of the foregoing methods, algorithms can be developed for power compensation based on magnet angular positions and/or magnet radial positions. As a result of such power compensation, the planar and/or radial non-uniformity of a thin film on a substrate may be significantly improved. Moreover, the methods described herein can reduce design of experiment budget and iteration for process optimization. Moreover, the methods described herein may be applied for magnetron angular and/or radial positions-based power compensation by different power supplies in PVD chamber including DC source, DC shield, AC bias, FO bias, EM coil, etc.

While the foregoing is directed to embodiments of the present disclosure, other and further embodiments of the disclosure may be devised without departing from the basic scope thereof.

1. A method of controlling processing of a substrate within a process chamber, comprising:
performing statistical analysis on measurements of deposition profile of at least one previously processed substrate processed in the process chamber, wherein the deposition profile is based at least on modulating a power parameter of at least one power supply affecting a magnetron in the process chamber;
determining, based on the statistical analysis, a model of the deposition profile as a function of at least the power parameter;
fitting the measurements of deposition profile to the model;
determining a power parameter setpoint for the at least one power supply using the fitted model based on a desired deposition profile of an unprocessed substrate; and
setting the power parameter setpoint for processing the unprocessed substrate.

2. The method according to claim 1, further comprising predicting a deposition profile using the model and the determined power parameter setpoint.

3. The method according to claim 1, wherein the measurements consist of measurements of a single previously processed substrate processed immediately before the unprocessed substrate.

4. The method according to claim 1, wherein the process chamber comprises an etching chamber and the power parameter setpoint controls a rate of material etching at a location on a surface of the substrate.

5. The method according to claim 1, wherein the process chamber comprises a deposition chamber and the power parameter setpoint controls a rate of material deposition at a location on a surface of the substrate.

6. The method according to claim 1, wherein the model is a function of the power parameter and at least one of an angular position or radial position of the magnetron relative to a reference location on a surface of the substrate.

7. The method according to claim 6, wherein determining the power parameter setpoint includes determining at least one of an angular position or radial position at which to set the power parameter setpoint.

8. An apparatus for controlling processing of a substrate within a process chamber including a moveable magnetron and at least one power supply, comprising:
a processor; and
a memory coupled to the processor, the memory having stored therein instructions executable by the processor to configure the apparatus to:
perform statistical analysis on measurements of deposition profile of at least one previously processed substrate processed in the process chamber, wherein the deposition profile is based at least on modulating a power parameter of the at least one power supply affecting the magnetron in the process chamber;
determine, based on the statistical analysis, a model of the deposition profile as a function of at least the power parameter;
fit the measurements of deposition profile to the model;
determine a power parameter setpoint for the at least one power supply using the fitted model based on a desired deposition profile of an unprocessed substrate; and
set the power parameter setpoint for processing the unprocessed substrate.

9. The apparatus according to claim 8, wherein the apparatus is further configured to predict a deposition profile using the model and the determined power parameter setpoint.

10. The apparatus according to claim 8, wherein the measurements of deposition profile consist of measurements of a single previously processed substrate processed immediately before the unprocessed substrate.

11. The apparatus according to claim 8, wherein the model of the deposition profile is a function of the power parameter and at least one of an angular position or a radial position of the magnetron relative to a reference location on a surface of the substrate.

12. The apparatus according to claim 11, wherein determining the power parameter setpoint includes determining at least one of an angular position or a radial position at which to set the power parameter setpoint.

13. A substrate processing system, comprising:
a process chamber, comprising:
a movable magnetron; and
at least one power supply affecting the magnetron; and
a controller comprising a processor and a memory coupled to the processor, the memory having stored therein instructions executable by the processor to configure the controller to:
perform statistical analysis on measurements of deposition profile of at least one previously processed substrate processed in the process chamber, wherein the deposition profile is based at least on modulating a power parameter of the at least one power supply affecting the magnetron in the process chamber;
determine, based on the statistical analysis, a model of the deposition profile as a function of at least the power parameter;
fit the measurements of deposition profile to the model;
determine a power parameter setpoint for the at least one power supply using the fitted model based on a desired deposition profile of an unprocessed substrate; and
set the power parameter setpoint for processing the unprocessed substrate.

14. The system according to claim 13, wherein the controller is further configured to predict a deposition profile using the model and the determined power parameter setpoint.

15. The system according to claim 13, wherein the measurements of deposition profile consist of measurements of a single previously processed substrate processed immediately before the unprocessed substrate.

16. The system according to claim 13, wherein the process chamber comprises an etching chamber and the power parameter setpoint controls a rate of material etching at a location on a surface of the substrate.

17. The system according to claim 13, wherein the process chamber comprises a deposition chamber and the power parameter setpoint controls a rate of material deposition at a location on a surface of the substrate.

18. The system according to claim 13, wherein the model of the deposition profile is a function of the power parameter and at least one of an angular position or a radial position of the magnetron relative to a reference location on a surface of the substrate.

19. The system according to claim 18, wherein determining the power parameter setpoint includes determining at least one of an angular position or a radial position at which to set the power parameter setpoint.

20. The system according to claim 13, wherein the process chamber is part of a cluster tool that also includes a metrology chamber, wherein the metrology chamber includes a measurement system for obtaining the measurements of the deposition profile after each unprocessed substrate is processed in the process chamber.
